(19) United States
(12) Patent Application Publication
(10) Pub. No.: US 2008/0002366 A1
(43) Pub. Date: Jan. 3, 2008

(54) HEAT SINK BACK PLATE MODULE

(75) Inventors: Ming-Fang Tsai, Taipei (TW); Chi-Chun Huang, Taipei (TW)

Correspondence Address: J C PATENTS, INC., 4 VENTURE, SUITE 250, IRVINE, CA, 92618, US

(73) Assignee: AMA PRECISION INC., Taipei (TW)

(21) Appl. No.: 11/748,120

(22) Filed: May 14, 2007

(30) Foreign Application Priority Data
Jun. 29, 2006 (TW) 95123490

(51) Int. Cl. H05K 7/20

(52) U.S. Cl. 361/704

(57) ABSTRACT

A heat sink back plate module suitable for fixing a heat sink on a heat source disposed on a motherboard is provided. A plurality of positioning holes is disposed around the heat source. The heat sink back plate module includes a plate body and a plurality of guideposts. The plate body having a plurality of locking holes is disposed under the motherboard. An internal thread is disposed in each locking hole. A portion of the locking holes are aligned to the positioning holes on the motherboard. The guideposts are assembled in the locking holes corresponding to the positioning holes. Each of the guideposts has an external thread disposed at one end. The external thread of the guidepost is locked in the internal thread of the locking hole corresponding to the positioning holes.

### CROSS-REFERENCE TO RELATED APPLICATION

This application claims the priority benefit of Taiwan application serial no. 95123490, filed Jun. 29, 2006. All disclosure of the Taiwan application is incorporated herein by reference.

### BACKGROUND OF THE INVENTION

1. Field of the Invention

The present invention relates to a back plate module, and more particularly, to a heat sink back plate module.

2. Description of Related Art

With the rapid development of in the electronic industry, the operating speed of electronic component such as a central processing unit (CPU) is being significantly increased and the amount of heat thus generated will also be increased accordingly. Therefore, most manufacturers dispose a heat sink atop the CPU on a motherboard to lower the internal operating temperature of the CPU. To meet the demand for a rapid heat dissipation of the CPU, the size and weight of the heat sink to be disposed on the CPU is gradually increased.

To prevent the weight of the heat sink from pulling the motherboard down as a result of the extended high-temperature state, thereby deforming the motherboard and subsequently leading to vibration that may break the motherboard, a heat sink back plate is normally assembled at the back of the motherboard. The back plate not only reinforces the structural strength of the motherboard, but also provides a tighter engagement between the bottom portion of the heat sink and the surface of the CPU.

It should be noted that a number of heat sink back plate designs now in the market barely meet the specification of the motherboard. In other words, those back plates in the market with guidepost function are single specification back plates and hence cannot be used as a common unit with a second specification. For example, the Intel fixed base has a corresponding back plate, a K8 fixed base has a corresponding back plate. In general, the back plate suitable for an Intel fixed base cannot be used as a back plate in the K8 fixed base. Therefore, if the user needs to switch to another motherboard with a different specification (for example, changing from a socket 478 motherboard to a LGA775 motherboard), the back plate of that particular motherboard has to be purchased leading to material waste. In addition, those back plates having guidepost function now sold on the market are the fixed types. The guideposts are normally riveted to the back plate or embedded in the back plate. Thus, a back plate with this design can hardly be used as a common unit in other motherboards having a different specification.

### SUMMARY OF THE INVENTION

Accordingly, at least one objective of the present invention is to provide a heat sink back plate module that can be used in a number of motherboards with different specifications.

At least another objective of the present invention is to provide a heat sink back plate module having a positioning function so that the time required to assemble the heat sink back plate to a motherboard is shortened.

To achieve these and other advantages and in accordance with the purpose of the invention, as embodied and broadly described herein, the invention provides a heat sink back plate module suitable for fixing a heat sink to a heat source on a motherboard. A plurality of positioning holes is disposed around the heat source. The heat sink back plate module includes a plate body and a plurality of guideposts. The plate body having a plurality of locking holes is disposed under the motherboard. An internal thread is disposed in each locking hole. A portion of the locking holes are aligned to the positioning holes on the motherboard. The guideposts are assembled in the locking holes corresponding to the positioning holes. Each of the guideposts has an external thread disposed at one end. The external thread of the guidepost is locked in the internal thread of the locking hole corresponding to the positioning hole.

In one embodiment of the present invention, a second internal thread is disposed at the other end of the guideposts. The heat sink further includes a plurality of locking elements. These locking elements are locked in the second internal thread of the guideposts so that the heat sink is fixed on the heat source.

In one embodiment of the present invention, the foregoing plate body is made of metal.

In one embodiment of the present invention, the foregoing plate body is made of plastic. The first internal thread is made of metal and the first internal thread is embedded in the locking hole.

In one embodiment of the present invention, the foregoing heat sink back plate module further includes a plastic film disposed on a surface of contact between the plate body and the motherboard.

In the heat sink back plate module of the present invention, the plate body has a plurality locking holes and a plurality of guideposts is disposed in the locking holes corresponding to the positioning holes. Therefore, the heat sink back plate module can be rapidly mounted into the positioning holes through the guideposts so that the locking elements of the heat sink and the guideposts are easily aligned and assembled to the second internal thread of the guideposts. Hence, the heat sink is tightly engaged to the surface of the heat source. When there is a need to switch the motherboard to another one having a different specification, the user only has to re-assemble a portion of the guideposts to locking holes corresponding to the positioning holes of the new motherboard. Thus, the heat sink back plate module is able to instantly match the new specification of the motherboard so that the heat sink back plate module can be smoothly assembled to the new motherboard.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a perspective view showing an assembled unit comprising a heat sink back plate module, a heat sink and a motherboard according to one preferred embodiment of the present invention.

FIG. 1B is a perspective view showing the heat sink back plate module, the heat sink and the motherboard in FIG. 1A dissembled from one another.

FIG. 2 is a perspective view showing the various components of the heat sink back plate module in FIG. 1B disassembled from one another.

FIG. 3 is a schematic cross-sectional view along line A-A′ of FIG. 2.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

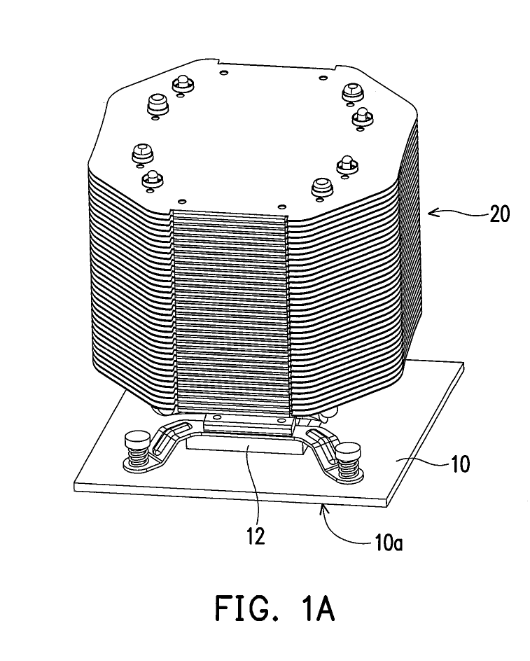

FIG. 1A is a perspective view showing an assembled unit comprising a heat sink back plate module, a heat sink and a motherboard according to one preferred embodiment of the present invention. FIG. 1B is a perspective view showing the heat sink back plate module, the heat sink and the motherboard in FIG. 1A dissembled from one another. As shown in FIGS. 1A and 1B, the heat sink back plate module 100 in the present embodiment is disposed on the back surface 10a of a motherboard 10, for example. The heat sink back plate module 100 is suitable for fixing a heat sink 20 on a heat source 12 on the motherboard 10. In the present embodiment, a plurality of positioning holes 14 surrounds the heat source 12 and the heat sink 20 is firmly disposed on the heat source 12 through a plurality of locking elements 30 to dissipate heat away from the heat source 12.

The foregoing locking elements 30 pass through the locking holes 22 on the heat sink 20 and lock onto the heat sink back plate module 100 so that the heat sink 20 is firmly attached to the surface of the heat source 12. In addition, the heat sink back plate module 100 is disposed on the back surface 10a of the motherboard 10 and suitable for fastening the heat sink 20 disposed on the heat source 12. Hence, the heat sink back plate module 100 is capable of reinforcing the structure of the motherboard 10. In the following, the heat sink back plate module 100 of the present embodiment is explained in more detail.

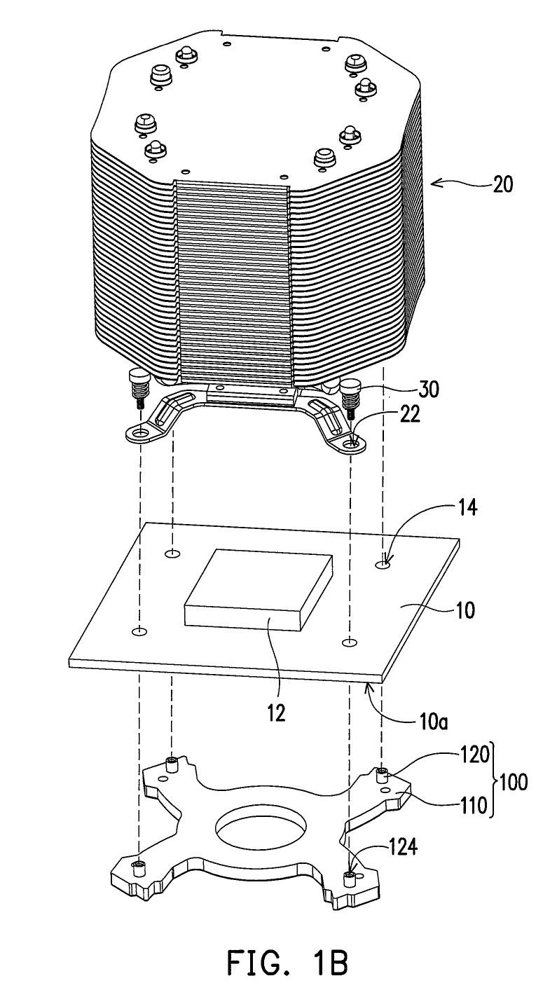

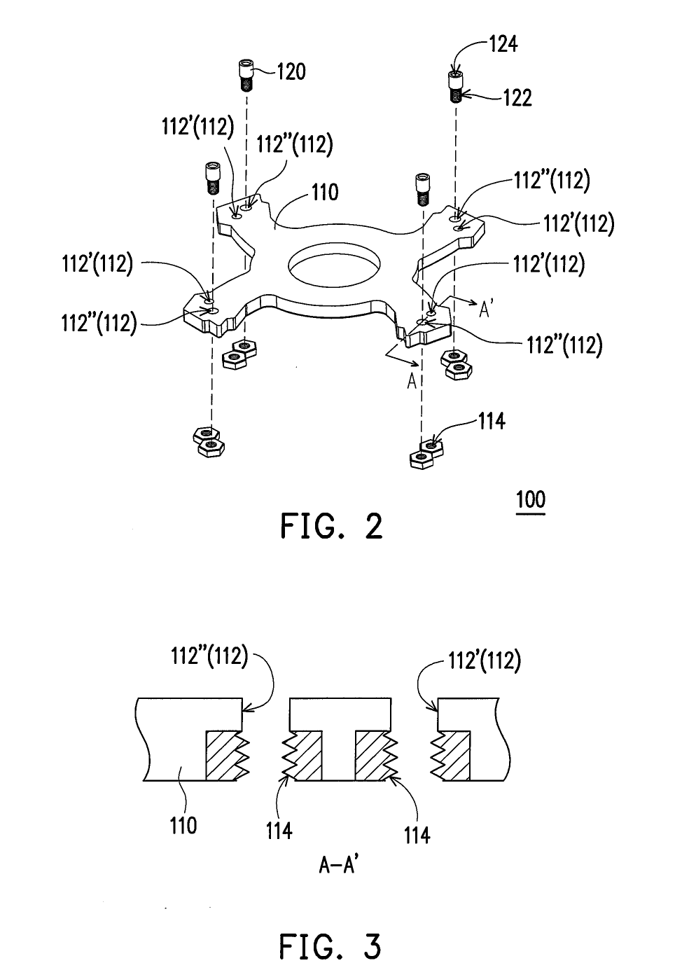

FIG. 2 is a perspective view showing the various components of the heat sink back plate module in FIG. 1B disassembled from one another. FIG. 3 is a schematic cross-sectional view along line A-A′ of FIG. 2. As shown in FIGS. 1B, 2, and 3, the heat sink back plate module 100 in the present embodiment mainly includes a plate body 110 and a plurality of guideposts 120. The plate body 110 having a plurality of locking holes 112 is disposed under the motherboard 10. Each locking hole 112 has a first internal thread 114. In addition, a portion of the locking holes 112′ correspond to a plurality of positioning holes 14 on the motherboard 10. The guideposts are assembled to a portion of the locking holes 112′ corresponding to the positioning holes 14. In the present embodiment, one end of each guidepost 120 has an external thread 122 and the guideposts 120 are locked on the first internal thread 114 of a portion of the locking holes 112′ through the external thread 122.

In the present embodiment, the plate body 110 is made of plastic and the first internal thread 114 is made of metal, for example. Furthermore, the first internal thread 114 is embedded within the locking hole 112. Therefore, the guidepost 120 is able to lock on the first internal thread 114 in the locking hole 112. In other embodiment, the plate body 110 can be made of metal so that the inner wall of the locking hole 12 is easily worked (by die-tapping) to form threads on the interior wall of the locking holes 112 for engaging with the guideposts 120. In addition, when the plate body 110 is fabricated from metal, the user needs to dispose a plastic film on the surface of contact between the plate body 110 and the motherboard 10 so that the heat sink back plate module 100 and the motherboard are electrically insulated. It should be noted that the plate body 110 is normally made of plastic to lower the cost of producing the heat sink back plate module 100. However, a first internal thread 114 made of metal is required to provide a locking mechanism to the guideposts 120.

In addition, the other end of the guideposts 120 may include a second internal thread 124. Then, the locking element 30 can be locked in the second internal thread 124 so that the heat sink 20 is fixed on the heat source 12. Obviously, the present invention is not limited to fixing the heat sink 20 on the heat source 12. For example, in other embodiment, the user may fix a retention module, used for latching the heat sink 20, to the motherboard 10 first (for example, the retention module is fixed on the mother board 10 using the locking relation between the locking elements and the second internal thread 124). As a result, the heat sink 20 is fixed on the heat source 12 through the retention module.

It should be noted that the guideposts 120 are assembled to a portion of the locking holes 112′ corresponding to the positioning holes 14. Therefore, the heat sink back plate module 100 can be rapidly slid into the positioning holes 14 through the guideposts 120. The heat sink 20 is firmly attached to the surface of the heat source 12 through the locking relation between the locking elements 30 and the heat sink back plate module 100. On the other hand, aside from a portion of the locking holes 112′ corresponding to the positioning holes 14, the plate body 110 also includes a plurality of locking holes 112″ that meet the specification of another motherboard. In other words, the locking holes 112″ correspond to the positioning holes of another motherboard. More specifically, when there is a need to switch for another motherboard, one only has to relocate the guideposts 120 originally locked in the locking hole 112′ to the locking holes 112″. The heat sink back plate module 100 can be rapidly slid into the positioning holes of the new motherboard through the guideposts 120. In other words, the heat sink back plate module 100 in the present embodiment can be used as a common unit for serving different types of motherboards.

In summary, the heat sink back plate module in the present invention has multiple groups of locking holes that correspond to different motherboard specifications on the plate body so that the guideposts can be assembled in locking holes according to a particular motherboard specification. Thus, compared with the conventional technique, the present invention has the following advantages:

1. Because the plate body has multiple groups of locking holes for different motherboard specification, the heat sink back plate module in the present invention is a product having wide and sharable applications. In other words, there is no need to purchase a new heat sink back plate module when the user needs to switch motherboard.

2. Because the heat sink back plate module in the present invention has a plurality of guideposts corresponding to the positioning holes on the motherboard, the heat sink back plate module can be easily assembled to the motherboard through the guideposts. Hence, the assembling time is shortened.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat sink back plate module suitable for fixing a heat sink to a heat source on a motherboard, wherein a plurality of positioning holes surrounds the heat source, the heat sink back plate module comprising:
a plate body, disposed under the motherboard, wherein the plate body has a plurality of locking holes with a first internal thread therein, and a portion of the locking holes correspond to the positioning holes; and
a plurality of guideposts, assembled in the portion of the locking holes corresponding to the positioning holes, wherein one end of each guidepost has an external thread and the external thread of the guideposts are locked in the first internal thread of a portion of the locking holes.

2. The heat sink back plate module of claim 1, wherein another end of each guidepost has a second internal thread and the heat sink comprises a plurality of locking elements such that the locking elements are locked in the second internal thread of the guideposts so that the heat sink is fixed on the heat source.

3. The heat sink back plate module of claim 1, wherein a material constituting the plate body comprises a metal.

4. The heat sink back plate module of claim 1, wherein a material constituting the plate body comprises a plastic and the material constituting the first internal thread comprises a metal, and the first internal thread is embedded within the locking holes.

5. The heat sink back plate module of claim 1, further comprising a plastic film disposed on a surface of contact between the plate body and the motherboard.
